(19) United States
(12) Patent Application Publication
(10) Pub. No.: US 2020/0072895 A1
(43) Pub. Date: Mar. 5, 2020

(54) METHOD FOR CALCULATING A REFLECTOGRAM TO ANALYSE FAULTS IN A TRANSMISSION LINE

(71) Applicant: COMMISSARIAT A L'ENERGIE ATOMIQUE ET AUX ENERGIES ALTERNATIVES, PARIS (FR)

(72) Inventor: Fabrice AUZANNEAU, MASSY (FR)

(21) Appl. No.: 16/467,979

(22) PCT Filed: Dec. 6, 2017
(86) PCT No.: PCT/EP2017/081631

§ 371 Date: Jun. 9, 2019

(30) Foreign Application Priority Data
Dec. 14, 2016 (FR) 1662396

(51) Int. Cl. G01R 31/08; G01R 31/11

(52) U.S. Cl. CPC G01R 31/088; G06F 17/15; G01R 31/11

(57) ABSTRACT

A method for calculating a reflectogram associated with a transmission line into which a reference signal is injected beforehand, the method includes the following iteratively executed steps: acquiring, at a current time i+dK, a measurement of dK samples of the signal after propagation thereof in the transmission line, determining a reflectogram R_{i+dK} at the current time i+dK, from a previous reflectogram Rᵢ, calculated at a previous time i, by performing the following operations for each value of the reflectogram: subtracting, from the previous reflectogram Rᵢ, at least one product of correlation between a number dK of samples of the signal that are measured at the previous time i and a number dK of corresponding samples of the reference signal that are injected into the transmission line at an injection time i′−dK. Adding, to the previous reflectogram Rᵢ, at least one product of correlation between a number dK of samples measured at the current time i+dK and a number dK of samples of the reference signal that are injected into the transmission line at an injection time i′.

The invention relates to the field of the analysis of faults impacting transmission lines, such as electric cables.

More precisely, the invention relates to the particular field of reflectometry applied to wired diagnostics that incorporates the field of detection, location and characterization of faults in single transmission lines or complex wired networks.

Known reflectometry methods operate in accordance with the following method. A controlled reference signal, for example a pulsed signal or else a multi-carrier signal, is injected at one end of the cable to be tested. More generally, in modern reflectometry methods, the reference signal that is used is chosen depending on its intercorrelation properties. The signal propagates along the cable and reflects off the singularities that it comprises.

A singularity in a cable corresponds to a modification of the propagation conditions of the signal in this cable. It is caused more often than not by a fault that locally modifies the characteristic impedance of the cable by bringing about a discontinuity in its linear electrical parameters.

The reflected signal is propagated back to the point of injection, and is then analyzed by the reflectometry system. The delay between the injected signal and the reflected signal makes it possible to locate one (or more) singularity (or singularities), corresponding to an electrical fault, in the cable. A fault may be caused by a short circuit, an open circuit or else local damage to the cable or even simple crimping of the cable.

The most significant processing operation and also the most expensive one in terms of calculation time in a reflectometry process relates to the calculation of a reflectogram that is the result of the intercorrelation between a copy of the test signal injected into the cable or network of cables and a measurement of this same signal after propagation thereof in the cable or network of cables.

The invention pertains to a particular method for calculating such a reflectogram, making it possible to reduce the calculating time necessary for execution thereof, and thus reduce the implementation complexity thereof.

The invention applies to any type of electric cable, in particular power transmission cables, in fixed or mobile installations. The cables in question may be coaxial, bifilar, in parallel lines, in twisted pairs or other cables.

Cables are omnipresent in all electrical systems in order to supply power or to transmit information. These cables are subjected to the same constraints as the systems that they link, and may be subject to failures. It is therefore necessary to be able to analyze their state and to provide information about the detection of faults, but also their location and their type, so as to assist with maintenance.

Conventional reflectometry methods enable this type of test. They use test or reference signals, also called probe signals or reflectometry signals. The form of these signals changes significantly during their outward-return propagation in a cable, these changes being the result of physical attenuation and dispersion phenomena.

Reflectometry methods use a principle close to that of radar: an electrical signal, the probe signal, which is often high-frequency or wideband, is injected at one or more locations of the cable or of the network of cables to be tested. The signal propagates in the cable or the network and returns a portion of its power when it encounters an electrical discontinuity. An electrical discontinuity may be caused for example by a connection, by the end of the cable or by an electrical fault at an arbitrary location of the cable. Analyzing the signals returned to the point of injection makes it possible to deduce therefrom information about the presence and the location of these discontinuities, and therefore of the possible faults. An analysis in the time or frequency domain is often performed. These methods are denoted using the acronyms TDR, stemming from the expression “time domain reflectometry”, and FDR, stemming from the expression “frequency domain reflectometry”. In particular, TDR time reflectometry methods analyze the measured signal by performing a calculation of intercorrelation between this measured signal and the injected signal for a plurality of time values. The result of this calculation is called time reflectogram. Analyzing the amplitude peaks of the reflectogram makes it possible to characterize the presence and the position of possible faults in the cable.

Calculating a time reflectogram therefore requires executing an operation of intercorrelation between a copy of the test signal and a measurement of the propagated signal in the cable to be tested. This calculation is expensive, in particular for embedded applications in which calculating resources are limited, as it consists of a sum of products.

One known solution for making the calculation of a reflectogram less expensive to execute involves using the mathematical properties of the Fourier transform. The principle involves calculating the intercorrelation result as the inverse Fourier transform of the product of the Fourier transforms of the two signals. This type of implementation makes it possible to reduce the implementation complexity by moving from the order of K² operations for a standard calculation to K.log₂(K) operations for the calculation by Fourier transform. K is the number of samples of each signal, or else the length of the intercorrelation.

However, the calculation by Fourier transform requires knowing all of the K samples of the measured signal and of the test signal before being able to execute the calculation. It is therefore necessary to wait for the K signal samples to have been injected and for the K samples of the propagated signal in the cable to have been measured in order to be able to calculate the reflectogram.

Furthermore, it is often necessary to take an average of a plurality of reflectograms in order to reduce the measurement noise, and therefore, in practice, it is necessary to wait for a duration equivalent to N*K periods of the injection system and/or of the measurement system, where N is the number of reflectograms necessary for the average calculation.

The invention proposes a method for simplifying the implementation of the calculation of a reflectogram and of an averaged reflectogram, in the context of a time reflectometry method. The invention thus makes it possible to speed up the calculation of a reflectogram in order to improve the processing speed.

The invention notably has the advantage of allowing a time reflectometry method to be implemented in an embedded device whose calculating resources are limited.

One subject of the invention is a computer-implemented method for calculating a reflectogram associated with a transmission line into which a reference signal is injected beforehand, a reflectogram being defined by a calculation, at a plurality of successive times, of the intercorrelation between the injected reference signal and a measurement of the reference signal after propagation thereof in the transmission line, said method comprising the following iteratively executed steps:
Acquiring, at a current time i+dK, a measurement of said signal after propagation thereof in the transmission line, said measurement comprising a number dK of samples,
Determining a reflectogram R_{i+dK} at the current time i+dK, from a previous reflectogram Rᵢ calculated at a previous time i, by performing the following operations for each value of the reflectogram:
   Subtracting, from the previous reflectogram Rᵢ, at least one product of correlation between a number dK of samples of the signal that are measured at the previous time i and a number dK of corresponding samples of the reference signal that are injected into the transmission line at an injection time i′−dK,
   Adding, to the previous reflectogram Rᵢ, at least one product of correlation between a number dK of samples measured at the current time i+dK and a number dK of corresponding samples of the reference signal that are injected into the transmission line at an injection time i′.

According to one particular aspect of the invention, at each iteration, the number dK of signal samples injected into the cable and the number of measured signal samples is equal to one sample.

According to one particular aspect of the invention, the reference signal is a chaotic signal.

According to one particular variant, the method according to the invention furthermore comprises a step of calculating the average of a plurality of reflectograms calculated successively, at times separated by a number of samples lower than the maximum number of samples K on which the intercorrelation is calculated.

According to one particular aspect of this variant, the number of samples between two successively calculated reflectograms is equal to four.

According to one particular aspect of the invention, a reflectogram is calculated from a number of measured samples of the reference signal after propagation thereof in the transmission line equal to K and from a number of injected reference signal samples equal to 2K−1.

Another subject of the invention is a method for analyzing a transmission line, comprising the steps of the method for calculating a reflectogram according to the invention and a step of analyzing the calculated reflectogram in order to identify at least one fault on the transmission line.

According to one variant embodiment, the analysis method according to the invention comprises a step of generating and of injecting the reference signal into the transmission line.

Another subject of the invention is a computer program comprising instructions for executing the method according to the invention when the program is executed by a processor.

Another subject of the invention is a recording medium able to be read by a processor and on which there is recorded a program comprising instructions for executing the method according to the invention when the program is executed by a processor.

Another subject of the invention is a device for calculating a reflectogram associated with a transmission line, comprising means for measuring a signal propagating in the transmission line and calculating means that are jointly configured so as to execute the method according to the invention.

Another subject of the invention is a system for diagnosing a transmission line, comprising a device for injecting a reference signal into the transmission line and a device for calculating a reflectogram according to the invention.

Other features and advantages of the present invention will become more clearly apparent upon reading the following description with reference to the appended drawings, in which:

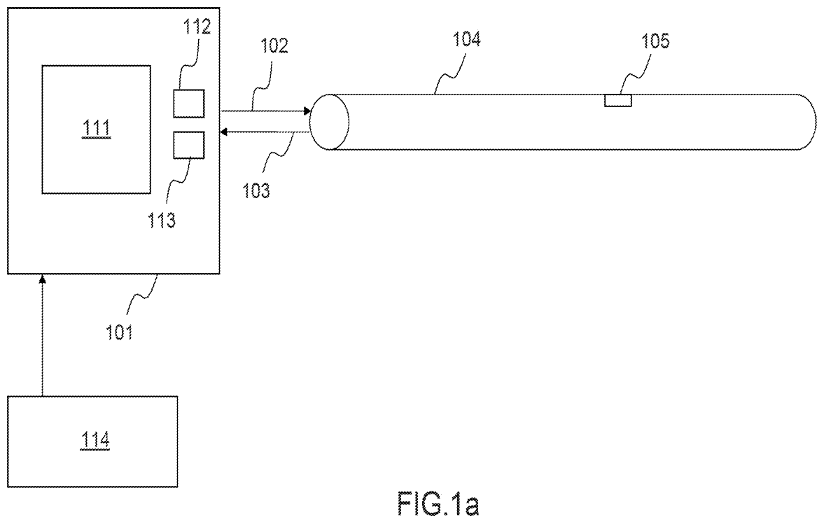

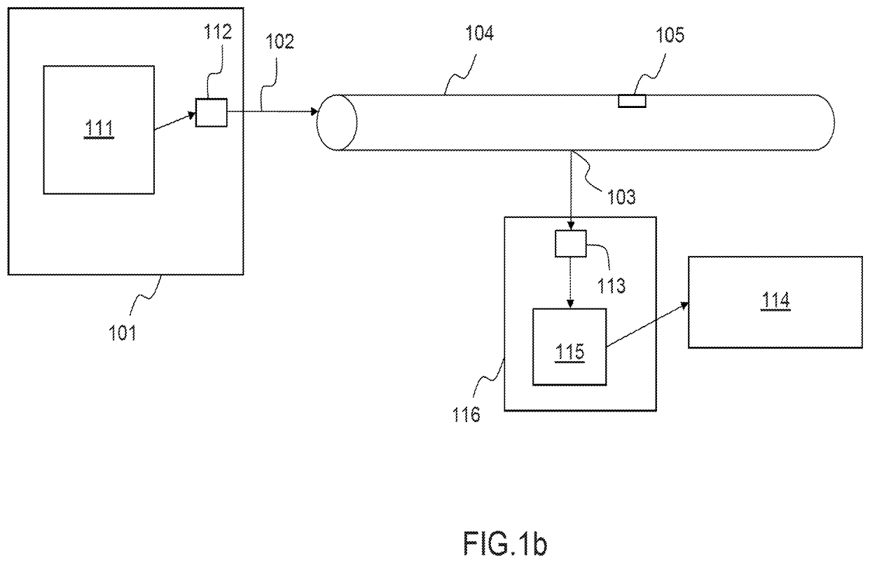

FIG. 1a shows a diagram of a first example of a reflectometry system configured so as to implement the invention,

FIG. 1b shows a diagram of a second example of a reflectometry system configured so as to implement the invention,

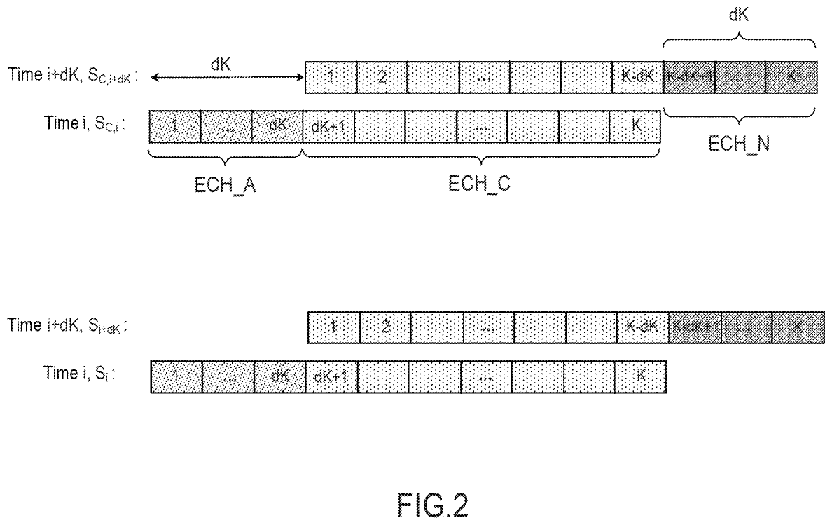

FIG. 2 shows a diagram illustrating a comparison of the signal injected at a point of the cable and of the signal measured at a point of the cable at two successive times,

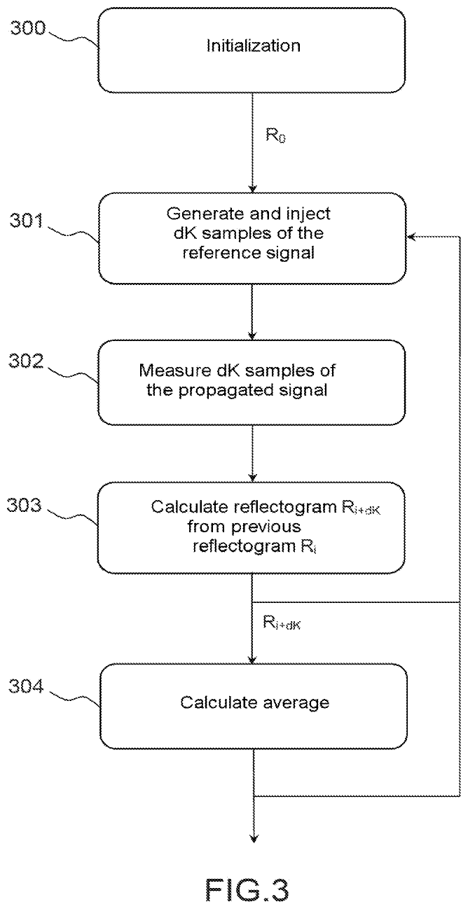

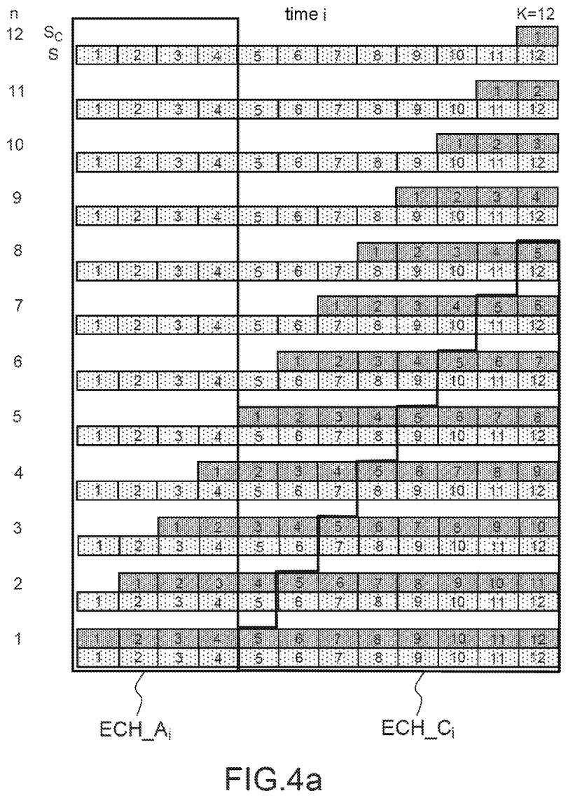

FIG. 3 shows a flowchart describing the steps for implementing the method according to the invention,

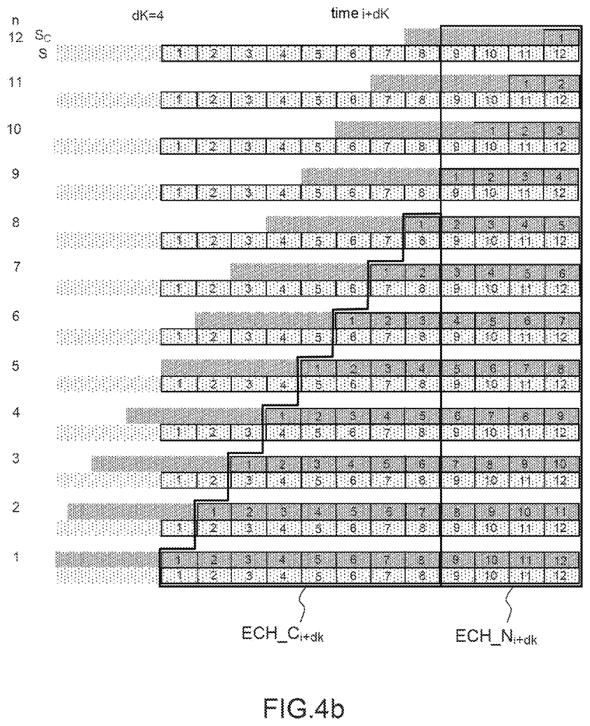

FIGS. 4a and 4b show two diagrams illustrating the operation of the invention for the calculation of two reflectograms determined at two successive times.

FIG. 1a describes an overview of an example of a reflectometry system configured so as to implement the invention. The invention is situated in the context of reflectometry methods for detecting, locating or characterizing faults impacting a cable or a cable network.

FIG. 1a shows a cable to be tested 104 that has a fault 105 at an arbitrary distance from an end of the cable. Without departing from the scope of the invention, the cable 104 may be replaced with a network of complex cables that are interconnected with one another. The single cable 104 of FIG. 1a is shown purely for the sake of illustration so as to explain the general principle of a reflectometry method.

A reflectometry system 101 according to the invention comprises an electronic component 111 of integrated circuit type, such as a programmable logic circuit, for example of FPGA type, or a microcontroller, designed to execute two functions. Firstly, the component 111 makes it possible to generate a reflectometry signal s(t) to be injected into the cable 104 undergoing testing. This digitally generated signal is then converted via a digital-to-analog converter 112 and then injected 102 at one end of the cable. The signal s(t) propagates in the cable and is reflected off the singularity brought about by the fault 105. The reflected signal is propagated back to the point of injection 106 and then captured 103, digitally converted via an analog-to-digital converter 113, and transmitted to the component 111. The electronic component 111 is furthermore designed to execute the steps of the method according to the invention that will be described hereinafter so as to determine a reflectogram or a plurality of reflectograms from the received signal s(t).

The reflectogram or reflectograms may be transmitted to a processing unit 114, of computer, personal digital assistant or other type, in order to display the results of the measurements on a human-machine interface.

The system 101 described in FIG. 1 is a completely non-limiting exemplary embodiment. In particular, the two functions executed by the component 111 may be separated into two separate components or devices, as is illustrated in the example of FIG. 1b. The point of injection and the point of measurement of the signal may also be taken at arbitrary locations of the cable, and not at the end thereof.

FIG. 1b shows a first device 101 dedicated to generating the reflectometry signal and to injecting it into the cable, and a second device 116 dedicated to measuring the signal at an arbitrary point of the cable and then to calculating the reflectogram via a component 115.

The component 115 may be an electronic component of integrated circuit type, such as a programmable logic circuit, for example of FPGA type or a microcontroller, for example a digital signal processor, that receives the signal measurements and is configured so as to execute the method according to the invention. The component 115 includes at least one memory for saving the last signal samples generated and injected into the cable and the last measured signal samples.

The invention aims to propose a novel calculation of the reflectogram that makes it possible to better distribute the large number of operations to be implemented by the component 115 in order to make the calculation more efficient.

FIG. 3 outlines the main steps of the method for calculating a reflectogram according to the invention.

The method starts with an initialization step 300, which comprises the following sub-steps:
Generating and injecting K first samples of the reference signal into the cable,
Measuring K samples of the propagated signal in the cable,
Initially calculating the reflectogram R₀ from the intercorrelation between the K samples of the injected signal and the K samples of the measured signal.

The initialization step 300 may also be made optional. In this case, the reflectogram R₀ is initialized at 0, and then the following steps of the method are executed directly. It is then necessary to wait for K samples of the propagated signal in the cable to have been measured in order to obtain a complete reflectogram, for the benefit of a calculation time saving from the start of the method.

The number K is a parameter of the invention and corresponds to the length (in number of samples) of the intercorrelation produced between the reference signal and the measured signal in order to calculate the reflectogram.

The measurement of the signal may be performed at the same time as the injection of the signal into the cable, or may be performed with an initial time shift.

In the case of a reflectometry device in accordance with the one described in FIG. 1b, for which the measurement device 116 is separate from the signal injection device 101, the measurement device 116 comprises a reference signal generator whose role is to generate a copy of the reference signal injected into the cable by the injection device 101. This copy is used to calculate the reflectogram.

The initialization step 300 produces a first, initial reflectogram, denoted R₀.

The method according to the invention continues by iteratively executing steps 301,302,303.

The two steps 301,302 of the method involve iteratively generating and injecting 301 dK samples of the reference signal into the cable, and then measuring 302 dK samples of the propagated signal in the cable. The number dK is a parameter of the invention and is preferably chosen so as to be much lower than the value of K. The value of dK is at least equal to 1.

Steps 301 and 302 are executed iteratively, in other words, at each time i, dK signal samples are injected into the cable and dK propagated signal samples are measured. The injection and the measurement of the signal are performed continuously throughout the entire duration of the analysis of the cable.

In the case of a reflectometry device in accordance with the one described in FIG. 1b, at each iteration, a copy of the dK signal samples injected into the cable are generated by the device 116 so as to be used to calculate the reflectogram.

At each time i, corresponding to an iteration, the K last samples of the injected signal and the K last samples of the measured signal are saved in a buffer or a local memory for the purpose of performing an intercorrelation calculation over a duration corresponding to the K last samples. It is recalled that the value of dK is assumed to be much lower than the value K. It is also assumed that the measured signal has been digitized beforehand in order to retain digital samples.

FIG. 2 illustrates a representation of the buffer containing the K last samples of the reference signal, on the one hand, and of the measured signal, on the other hand, at two successive times i and i+dK. Between these two successive times, a number dK of new signal samples are injected into the cable and the same number dK of new signal samples are measured.

The upper part of FIG. 2 shows the buffer S_{c,i} containing the samples of the reference signal that are saved at the time i and the buffer S_{c,i+dK} containing the samples of the reference signal that are saved at the following time i+dK.

The dK oldest samples of the buffer S_{c,i} (denoted ECH-A in FIG. 2) are deleted from the buffer S_{c,i+dK} at the following time i+dK. The K−dK most recent samples of the buffer S_{c,i} (denoted ECH-C in FIG. 2) are shifted in the buffer S_{c,i+dK} at the following time i+dK. Lastly, the buffer S_{c,i+dK} contains dK new samples (denoted ECH-N in FIG. 2) at the following time i+dK.

The lower part of FIG. 2 shows, in the same way, the buffer Sᵢ containing the samples of the measured signal that are saved at the time i and the buffer S_{i+dK} containing the samples of the measured signal that are saved at the following time i+dK.

It may be seen from FIG. 2 that, at two successive times i and i+dK, the buffer containing the K last samples of the reference signal has K−dK identical values. Likewise, at two successive times i and i+dK, the buffer containing the K last samples of the measured signal also has K−dK identical values.

A value Rᵢ(n) of the reflectogram Rᵢ at the time i corresponds to the intercorrelation between the samples of the buffer S_{c,i} containing the K last samples of the reference signal and the samples of the buffer Sᵢ containing the K last samples of the measured signal. This calculation is given by relationship (1) below.

Rᵢ(n)=(S_{c}*S)ᵢ(n)=Σⱼ₌₁^{K-n+1}S_{c,i}(j).Sᵢ(n+j−1) (1)

The index n varies over all of the time values for which the reflectogram Rᵢ is calculated. Relationship (1) therefore gives a value of the reflectogram Rᵢ for a time instant of index n.

To generate a complete reflectogram, it is necessary to execute relationship (1) while varying the index n over the whole time interval corresponding to the duration of the reflectogram. The index n thus varies between 1 and K.

The value of index n of the reflectogram Rᵢ calculated at the time i may be broken down into two sums, on the basis of relationship (1), which becomes relationship (2):

Rᵢ(n)=Σⱼ₌₁^{dK}S_{c,i}(j).Sᵢ(n+j−1)+Σ_{j=dK+1}^{K-n+1}S_{c,i}(j).Sᵢ(n+j−1) (2)

In the same way, the value of index n of the reflectogram R_{i+dK} calculated at the time i+dK may be broken down into two sums, as illustrated by relationship (3):

R_{i+dK}(n)=Σⱼ₌₁^{K-n-dK+1}S_{c,i+dK}(j).S_{i+dK}(n+j−1)+Σ_{j=K-n-dK+2}^{K-n+1}S_{c,i+dK}(j).S_{i+dK}(n+j−1) (3)

In accordance with the illustration of FIG. 2, it is known that the values ECH_C of the samples of the reference signal S_{c} stored at the time i+dK, ranging between indices 1 and K−dK, are identical to the values of the samples of the reference signal S_{c} stored at the time i, ranging between the indices dK+1 and K. The same conclusion applies for the measured signal S.

On the basis of these observations and of relationships (2) and (3), it is possible to deduce therefrom the recurrence relationship (4) between a value of the reflectogram calculated at the time i and the same value of index n of the reflectogram calculated at the following time i+dK:

$${R}_{i + dK} ( n ) = {R}_{i} ( n ) - {\sum }_{j = 1}^{dK} {S}_{c , i} ( j ) \cdot {S}_{i} ( n + j - 1 ) + {\sum }_{j = K - n - dk + 2}^{K - n + 1} {S}_{c , i + dK} ( j ) \cdot {S}_{i + dK} ( n + j - 1 ) \qquad ( 4 )$$

The values of the reflectogram at a time i+dK are thus determined from the values of the reflectogram at a previous time i in step 303 of the method according to the invention.

Step 303 thus involves subtracting, from the previous reflectogram Rᵢ, the products of correlation between the dK samples of the signal that are measured at the previous time i and a number dK of corresponding samples of the reference signal that are injected into the transmission line at the time i, and then adding, to the previous reflectogram Rᵢ, the products of correlation between the dK new samples measured at the current time i+dK and a number dK of corresponding samples of the reference signal that are injected into the transmission line at the current time i+dK.

The calculation of the current reflectogram performed in step 303 thus comprises a substantially lower number of operations to be performed. A minimum number of operations is achieved for a value of dK equal to 1 sample.

Formulae (1) to (4) are given with the consideration that the time of injection of new samples of the reference signal into the cable and the time of measurement of new samples of the propagated signal in the cable are identical and correspond to the index i. Without loss of generality, the injection time i′ and the measurement time i may be different, and relationships (1) to (4) may then be rewritten by replacing i with i′ in the expressions for the measured signal S. The injection of the signal and measurement thereof must however be synchronized and operate at an identical sampling rate.

Steps 301, 302, 303 are iterated for a duration corresponding to the duration of analysis of the cable.

Step 303 is executed for all of the values of a reflectogram. The calculation explained in relationship (4) is thus executed in parallel for n values of a reflectogram, corresponding to n successive time indices.

FIGS. 4a and 4b illustrate this parallel calculation for a reflectogram comprising 12 values, a value of K equal to 12 signal samples and a value of dK equal to 4 signal samples.

FIG. 4a shows, for each value of index n of the reflectogram Rᵢ(n) to be calculated at the time i, the buffer Sc comprising the K last values of the injected signal and the buffer S comprising the K last values of the measured signal. The index n varies between 1 and K.

FIG. 4b shows the same buffers Sc,S for the calculation of the reflectogram at the following time i+dK.

Each value of a reflectogram is obtained by performing the intercorrelation between the K samples of the measured signal S, which are identical for each value n of the reflectogram, and a variable number of samples of the reference signal S_{c}, this number varying between 1 and K. In other words, for each value n of the reflectogram, the samples, in the buffer, of the reference signal Sc are shifted by one sample.

The groups of samples ECH_C, and ECH_C_{i+dK} in bold in the two FIGS. 4a, 4b correspond to the measured signal samples that are common between the times i and i+dK. In other words, these are samples that are identical in memory in the buffers at these two successive times.

The samples of index 9 to 12 (that is to say K−dK+1 to K) marked ECH_N_{i+dK} in the buffers at the time i+dK correspond to the dK new samples injected into the cable and measured.

The samples of index 1 to 4 (that is to say 1 to dK) marked ECH_A, in the buffers at the time i correspond to the samples stored at the time i that are deleted from the buffers at the time i+dK.

One particular exemplary embodiment of the invention relates to the case in which the number dK of samples injected and then measured at each time i is equal to 1. This scenario is the one for which the number of operations necessary at each iteration to calculate a reflectogram is lowest.

For this particular embodiment, step 303 of calculating the reflectogram may be simplified on the basis of equation (4) as follows.

At the current time i, the product S(n)*S_{c}(1) is subtracted from each value indexed n of the reflectogram Rᵢ(n), and then the samples in the two buffers S and S_{c} are shifted by a value, and the new sample of the injected reference signal is recorded in the buffer S_{c} and the new sample of the measured signal is recorded in the buffer S. Lastly, the product S(K)*S_{c}(K+1−n) is added to each value indexed n of the reflectogram Rᵢ(n).

In an optional step 304, the reflectograms calculated in step 03 may be averaged in order to combat the influence of noise that impacts the measured signal.

The average R_{moy}ⁿ of the reflectograms may be taken for example by iteratively calculating an update to the current average R_{moy}^{c} with respect to the previous average R_{moy}^{a} via formula (5), in which Rᵢ is the last calculated reflectogram:

$${R}_{moy}^{n} = \frac{{N}_{moy} {R}_{moy}^{a} + {R}_{i}}{{N}_{moy} + 1} \\ {N}_{moy} = {N}_{moy} + 1 \qquad ( 5 )$$

In one variant embodiment, the buffer S_{c} that makes it possible to save the last samples of the reference signal injected into the cable, and which are required to calculate a reflectogram, may be enlarged so as to no longer save K samples, but rather 2K−1, at each time. In this case, a value of the reflectogram is still calculated by performing the intercorrelation between K samples of the buffer S comprising the measured signal and K samples of the buffer S_{c} comprising the injected reference signal. For each value of index i<n of the reflectogram, the K selected samples are shifted in order to calculate a sample in the buffer S_{c}.

This variant has the advantage of improving the calculation accuracy for a reflectogram due to the fact that a longer duration of the reference signal is taken into account in the calculation of the reflectogram. Calculating the reflectogram in accordance with this variant thus makes it possible to maintain the coherence between the multiple injected signal copies contained in the measured signal and the signal with which said measured signal is correlated.

The principle of calculating the reflectogram that is implemented in step 303 remains similar. By way of example, when dK has the value 1, step 303 may be executed as follows.

At the current time i, the product S(1)*S_{c}(K+1−n) is subtracted from each value indexed n of the reflectogram Rᵢ(n), and then the samples in the two buffers S and S_{c} are shifted by a value, and the new sample of the injected reference signal is recorded in the buffer S_{c} and the new sample of the measured signal is recorded in the buffer S. Lastly, the product S(K)*S_{c}(K+1−n) is added to each value indexed n of the reflectogram Rᵢ(n).

The invention advantageously applies for what are known as chaotic signals that are generated by way of an incremental construction. In other words, each sample Sₙ is generated from the previous sample Sₙ₋₁: Sₙ=f(Sₙ₋₁).

This type of signal has the particular feature of allowing the signal to be injected into the cable as required for a long duration, without having to save a large number of samples.

One particular property of chaotic signals is that the evolution of a reflectogram calculated for these signals is such that the contribution of noise varies greatly over a short duration. It is thus possible to average reflectograms calculated at close times and therefore to implement a reflectogram calculation of the type described in FIG. 3. The deviation between two averaged reflectograms may typically be greater than or equal to four periods of sample injections. One advantage of the invention applied to chaotic signals is that it makes it possible to perform an average reflectogram calculation over a shorter duration than conventional methods, and thus to produce a final result more quickly.

The invention also has the advantage of substantially reducing the influence of noise on the calculated reflectograms in comparison with a method based on the use of Fourier transforms.

This advantage may be illustrated by way of a numerical example. Considering a time horizon corresponding to 1000 clock times (therefore 1000 generated signal samples, injected into the cable and measured after propagation in the cable), and setting the number K of samples used to calculate a reflectogram to 100, a method based on the use of Fourier transforms makes it possible to calculate 10 reflectograms during this duration, and therefore to reduce the noise by a factor 20*log₁₀(10)=20 dB after averaging.

By contrast, the invention makes it possible, in the same duration, to produce 900/4=225 reflectograms (taking dK to be equal to 4), thereby leading to a noise reduction in the reflectogram obtained after averaging by a factor 20*log10(225)=47 dB.

The invention thus makes it possible to effectively combat the influence of measurement noise.

The method according to the invention may be implemented on the component 115 on the basis of hardware elements and/or software elements.

The method according to the invention may be implemented directly by an embedded processor or in a specific device. The processor may be a generic processor, a specific processor, an application-specific integrated circuit (ASIC) or a field-programmable gate array (FPGA). The device according to the invention may use one or more dedicated electronic circuits or a general-purpose circuit. The technique of the invention may be carried out on a reprogrammable calculation machine (a processor or a microcontroller for example) executing a program comprising a sequence of instructions, or on a dedicated calculation machine (for example a set of logic gates such as an FPGA or an ASIC, or any other hardware module).

The method according to the invention may also be implemented exclusively as a computer program, the method then being applied to previously recorded signal measurements. In such a case, the invention may be implemented as a computer program comprising instructions for the execution thereof. The computer program may be recorded on a recording medium that is able to be read by a processor.

The reference to a computer program that, when it is executed, performs any one of the previously described functions is not limited to an application program running on a single host computer. On the contrary, the terms computer program and software are used here in a general sense to refer to any type of computer code (for example, application software, firmware, microcode, or any other form of computer instruction) that may be used to program one or more processors so as to implement aspects of the techniques described here. The computing means or resources may notably be distributed (“cloud computing”), possibly using peer-to-peer technologies. The software code may be executed on any suitable processor (for example a microprocessor) or processor core or a set of processors, whether they are provided in a single calculating device or distributed between several calculating devices (for example such as possibly accessible in the environment of the device). The executable code of each program allowing the programmable device to implement the process according to the invention may be stored for example in the hard disk or in read-only memory. Generally speaking, the program or programs may be loaded into one of the storage means of the device before being executed. The central unit is able to command and direct the execution of the instructions or software code portions of the program or programs according to the invention, which instructions are stored in the hard disk or in the read-only memory or else in the other abovementioned storage elements.

1. A computer-implemented method for calculating a reflectogram associated with a transmission line into which a reference signal is injected beforehand, a reflectogram being defined by a calculation, at a plurality of successive times, of the intercorrelation between the injected reference signal and a measurement of the reference signal after propagation thereof in the transmission line, said method comprising the following iteratively executed steps:
acquiring, at a current time i+dK, a measurement of said signal after propagation thereof in the transmission line, said measurement comprising a number dK of samples,
determining a reflectogram R_{i+dK} at the current time i+dK, from a previous reflectogram Rᵢ calculated at a previous time i, by performing the following operations for each value of the reflectogram:
subtracting, from the previous reflectogram Rᵢ, at least one product of correlation between a number dK of samples of the signal that are measured at the previous time i and a number dK of corresponding samples of the reference signal that are injected into the transmission line at an injection time i′−dK,
adding, to the previous reflectogram Rᵢ, at least one product of correlation between a number dK of samples measured at the current time i+dK and a number dK of corresponding samples of the reference signal that are injected into the transmission line at an injection time i′.

2. The method for calculating a reflectogram of claim 1, wherein, at each iteration, the number dK of signal samples injected into the cable and the number of measured signal samples is equal to one sample.

3. The method for calculating a reflectogram of claim 1, wherein the reference signal is a chaotic signal.

4. The method for calculating a reflectogram of claim 3, furthermore comprising a step of calculating the average of a plurality of reflectograms calculated successively, at times separated by a number of samples lower than the maximum number of samples K on which the intercorrelation is calculated.

5. The method for calculating a reflectogram of claim 4, wherein the number of samples between two successively calculated reflectograms is equal to four.

6. The method for calculating a reflectogram of claim 1, wherein a reflectogram is calculated from a number of measured samples of the reference signal after propagation thereof in the transmission line equal to K and from a number of injected reference signal samples equal to 2K−1.

7. A method for analyzing a transmission line into which a reference signal is injected beforehand, the method comprising calculating a reflectogram being defined by a calculation, at a plurality of successive times, of the intercorrelation between the injected reference signal and a measurement of the reference signal after propagation thereof in the transmission line, said method comprising the following iteratively executed steps:
acquiring, at a current time i+dK, a measurement of said signal after propagation thereof in the transmission line, said measurement comprising a number dK of samples,
determining a reflectogram R_{i+dK} (at the current time i+dK, from a previous reflectogram Rᵢ calculated at a previous time i, by performing the following operations for each value of the reflectogram:
subtracting, from the previous reflectogram Rᵢ, at least one product of correlation between a number dK of samples of the signal that are measured at the previous time i and a number dK of corresponding samples of the reference signal that are injected into the transmission line at an injection time i′−dK,
adding, to the previous reflectogram Rᵢ, at least one product of correlation between a number dK of samples measured at the current time i+dK and a number dK of corresponding samples of the reference signal that are injected into the transmission line at an injection time i′, and analyzing the calculated reflectogram in order to identify at least one fault on the transmission line.

8. The method for analyzing a transmission line of claim 7, comprising a step of generating and of injecting the reference signal into the transmission line.

9. A computer program comprising instructions stored on a tangible non-transitory storage medium for executing on a processor a method for calculating a reflectogram associated with a transmission line into which a reference signal is injected beforehand, a reflectogram being defined by a calculation, at a plurality of successive times, of the intercorrelation between the injected reference signal and a measurement of the reference signal after propagation thereof in the transmission line, said method comprising the following iteratively executed steps:
acquiring, at a current time i+dK, a measurement of said signal after propagation thereof in the transmission line, said measurement comprising a number dK of samples,
determining a reflectogram R_{i+dK} at the current time i+dK, from a previous reflectogram Rᵢ calculated at a previous time i, by performing the following operations for each value of the reflectogram:
subtracting, from the previous reflectogram Rᵢ, at least one product of correlation between a number dK of samples of the signal that are measured at the previous time i and a number dK of corresponding samples of the reference signal that are injected into the transmission line at an injection time i′−dK,
adding, to the previous reflectogram Rᵢ, at least one product of correlation between a number dK of samples measured at the current time i+dK and a number dK of corresponding samples of the reference signal that are injected into the transmission line at an injection time i′.

10. A tangible non-transitory processor-readable recording medium on which there is recorded a program comprising instructions for executing a method for calculating a reflectogram associated with a transmission line into which a reference signal is injected beforehand, a reflectogram being defined by a calculation, at a plurality of successive times, of the intercorrelation between the injected reference signal and a measurement of the reference signal after propagation thereof in the transmission line, said method comprising the following iteratively executed steps:
acquiring, at a current time i+dK, a measurement of said signal after propagation thereof in the transmission line, said measurement comprising a number dK of samples,
determining a reflectogram R_{i+dK} at the current time i+dK, from a previous reflectogram Rᵢ calculated at a previous time i, by performing the following operations for each value of the reflectogram:
subtracting, from the previous reflectogram Rᵢ, at least one product of correlation between a number dK of samples of the signal that are measured at the previous time i and a number dK of corresponding samples of the reference signal that are injected into the transmission line at an injection time i′−dK,
adding, to the previous reflectogram Rᵢ, at least one product of correlation between a number dK of samples measured at the current time i+dK and a number dK of corresponding samples of the reference signal that are injected into the transmission line at an injection time i′.

11. A device for calculating a reflectogram associated with a transmission line, comprising a measurement device for measuring a reference signal propagating in the transmission line and a calculator that are jointly configured so as to execute a method for calculating a reflectogram associated with a transmission line into which a reference signal is injected beforehand, a reflectogram being defined by a calculation, at a plurality of successive times, of the intercorrelation between the injected reference signal and a measurement of the reference signal after propagation thereof in the transmission line, said method comprising the following iteratively executed steps:
acquiring, at a current time i+dK, a measurement of said signal after propagation thereof in the transmission line, said measurement comprising a number dK of samples,
determining a reflectogram R_{i+dK} (at the current time i+dK, from a previous reflectogram Rᵢ calculated at a previous time i, by performing the following operations for each value of the reflectogram:
subtracting, from the previous reflectogram Rᵢ, at least one product of correlation between a number dK of samples of the signal that are measured at the previous time i and a number dK of corresponding samples of the reference signal that are injected into the transmission line at an injection time i′−dK,
adding, to the previous reflectogram Rᵢ, at least one product of correlation between a number dK of samples measured at the current time i+dK and a number dK of corresponding samples of the reference signal that are injected into the transmission line at an injection time i′.

12. A system for diagnosing a transmission line, comprising a device for injecting a reference signal into the transmission line and the device for calculating a reflectogram of claim 11.
